(19) United States
(12) Patent Application Publication
(10) Pub. No.: US 2025/0328918 A1
(43) Pub. Date: Oct. 23, 2025

(54) TECHNOLOGIES FOR ASSESSING BOUNDARIES OF INTENDED USE DOMAIN BASED ON VALIDATION SPACE

(71) Applicant: UL LLC, Northbrook, IL (US)

(72) Inventors: Sachin Rai, Bengaluru (IN); Dirk Mueller, Bad Soden A/Ts. (DE)

(21) Appl. No.: 18/642,347

(22) Filed: Apr. 22, 2024

(51) Int. Cl. G06Q 30/018; G06F 30/20

(52) U.S. Cl. CPC G06Q 30/018; G06F 30/20

(57) ABSTRACT

Systems and methods for using a simulation model to assess compliance of a product having a design that extends beyond a validation space of the simulation model are provided. According to certain aspects, systems and methods may verify and validate a simulation model associated with a product and with a given validation space. The systems and methods may assess compliance, with a standard, of a product that extends beyond the validation space by calculating a correlation factor based on characteristics product designs, and using the correlation factor with the verified and validated simulation model.

### FIELD

The present disclosure is directed to improvements to simulation model technologies. More particularly, the present disclosure is directed to technologies for assessing product compliance outside the validation spaces of simulation models.

### BACKGROUND

Simulation models are powerful tools used to represent complex systems, predict outcomes, and explore scenarios. These models are employed across various domains, including engineering, economics, environmental science, and healthcare. Generally, they simulate real-world processes, which enables individuals to understand their behavior and make informed decisions. A simulation model typically undergoes verification to ensure that the model is correctly implemented, adheres to its design specifications, and accurately represents the underlying system. Once verified, the simulation model is validated, which involves comparing model predictions with real-world observations, historical data, or experiments. Simulation models inherently contain uncertainties due to simplifications, approximations, and variability in input parameters. Uncertainty quantification aims to quantify these uncertainties by providing confidence intervals for predictions.

A given simulation model has a specific purpose or validation space, which defines the context in which the model is valid and is essential to understand the limitations and assumptions of the simulation model. Testing product parameters beyond the validation space and into an intended use domain can lead to misleading results, which risks safety, financial losses, or flawed policy decisions. Accordingly, there is an opportunity for systems and methods to address these challenges.

### SUMMARY

In an embodiment, a computer-implemented method of assessing compliance of products defined by virtual product designs is provided. The computer-implemented may include: accessing, by a computer processor, a simulation model associated with (i) a physical product and (ii) a certification; physically testing, using a physical test, a set of initial physical products respectively having a set of initial physical design configurations, the physically testing resulting in a set of physical test data; virtually testing, using a virtual test, a set of initial virtual products respectively having a set of initial virtual design configurations, the virtually testing resulting in a set of virtual test data; verifying, by the computer processor, the simulation model using the set of virtual test data; validating, by the computer processor, the simulation model using the set of physical test data, wherein the simulation model that was verified and validated has a validation space; and determining whether a subsequent product having a subsequent virtual design configuration outside the validation space complies with the certification, including: comparing the subsequent virtual design configuration to another design configuration associated with another product, based on the comparing, calculating a correlation factor associated with the subsequent product, and determining, based on the correlation factor using the simulation model that was verified and validated, whether the subsequent product would comply with the certification.

In a further embodiment, a system for assessing compliance of products defined by virtual product designs is provided. The system may include: a physical testing machine configured to physically test a set of initial physical products respectively having a set of initial physical design configurations, the physical testing resulting in a set of physical test data; a memory storing a set of computer-readable instructions; and at least one processor interfaced with the memory. The at least one processor may be configured to execute the set of computer-readable instructions to cause the at least one processor to: access a simulation model associated with (i) a physical product and (ii) a certification, virtually test, using a virtual test, a set of initial virtual products respectively having a set of initial virtual design configurations, the virtually testing resulting in a set of virtual test data, verify the simulation model using the set of virtual test data, validate the simulation model using the set of physical test data, wherein the simulation model that was verified and validated has a validation space, and determine whether a subsequent product having a subsequent virtual design configuration outside the validation space complies with the certification, including: compare the subsequent virtual design configuration to another design configuration associated with another product, based on the comparing, calculate a correlation factor associated with the subsequent product, and determine, based on the correlation factor using the simulation model that was verified and validated, whether the subsequent product would comply with the certification.

A non-transitory computer-readable storage medium configured to store instructions executable by a computer processor is provided. The instructions may include: instructions for accessing a simulation model associated with (i) a physical product and (ii) a certification; instructions for accessing a set of physical test data resulting from physically testing, using a physical test, a set of initial physical products respectively having a set of initial physical design configurations; instructions for virtually testing, using a virtual test, a set of initial virtual products respectively having a set of initial virtual design configurations, the virtually testing resulting in a set of virtual test data; instructions for verifying the simulation model using the set of virtual test data; instructions for validating the simulation model using the set of physical test data, wherein the simulation model that was verified and validated has a validation space; and instructions for determining whether a subsequent product having a subsequent virtual design configuration outside the validation space complies with the certification, including: instructions for comparing the subsequent virtual design configuration to another design configuration associated with another product, instructions for, based on the comparing, calculating a correlation factor associated with the subsequent product, and instructions for determining, based on the correlation factor using the simulation model that was verified and validated, whether the subsequent product would comply with the certification.

### BRIEF DESCRIPTION OF THE FIGURES

FIG. 1 depicts an overview of components and entities associated with the systems and methods, in accordance with some embodiments.

FIG. 2 depicts an example chart illustrating an existing simulation model technique.

FIG. 3 depicts various verification and validation functionalities associated with an example model compliance, in accordance with some embodiments.

FIG. 4 depicts an example chart illustrating an improved simulation model technique, in accordance with some embodiments.

FIG. 5 depicts an example chart illustrating various factors used to calculate a correlation or scaling factor, in accordance with some embodiments.

FIG. 6 depicts an example chart illustrating a verification of a correlation or scaling factor using simulation and testing results, in accordance with some embodiments.

FIG. 7 illustrates an example flow diagram of assessing compliance of products defined by virtual product designs, in accordance with some embodiments.

FIG. 8 is an example hardware diagram of a server configured to perform various functionalities, in accordance with some embodiments.

### DETAILED DESCRIPTION

The present embodiments may relate to, inter alia, improved simulation model technologies. According to certain aspects, the systems and methods may employ a verified and validated simulation model to determine compliance, with a standard or certification, of a test product having a configuration that extends beyond the validation space of the simulation model. In particular, the systems and methods may facilitate a comparison of product configurations to determine a correlation factor that the systems and methods use in combination with the simulation model to assess compliance of the test product with the standard or certification.

Generally, the predictive accuracy of a simulation model refers to its ability to determine results that correctly match real-world behavior beyond the exact conditions where simulation validation has occurred (i.e., the validation space of the simulation model). However, the degree of predictive confidence depends heavily on the relationship between validation points, validation space, and ultimately the intended use domain that the simulation targets.

Validation points represent specific scenarios and data where simulation outputs have been compared against experimental results to establish fidelity and accuracy. However, no simulation can be validated at all imaginable points across wide domains of applicability. Instead, validation occurs over a bounded multi-dimensional space of parameters, conditions, geometries, and operation envelopes. This validation space establishes the region where accuracy has been sampling checked via discrete validation points.

An intended use domain encompasses the full range of conditions under which the end users desire reliable predictions from the simulation. This can include extrapolation well beyond original validation data. A simulation's predictive capability is therefore bounded by its validation space. Predictions within this domain carry confidence in accuracy established at validation points. However, intended use conditions that stretch far beyond areas covered by validation data generally lack a sound basis for predictive confidence without further uncertainty quantification.

Expanding the validation space with more validation points and physics-based bench testing serves to enhance the credible predictive range of simulation models. However, this expansion requires further testing which is costly and time consuming. Additionally, conventional simulation models do not offer reliable predictions beyond their validation spaces.

There are several drawbacks if a validation space of a simulation does not sufficiently align or overlap with an intended use domain. In particular, this creates a lack of predictive confidence where there are large portions of the intended use conditions where the simulation's fidelity and accuracy has not been firmly established. Thus, using the simulation for predictions in these unvalidated areas carries high uncertainty. Additionally, without insight from validation data on the limitations of the simulation, there is a risk that end-users may apply the tool carelessly beyond its validation space based on false confidence, leading to faulty or even dangerous decisions.

Further, operating conditions that the customers desire which extend beyond the validation space may uncover new regions where the simulation fails or breaks down. Without sampling these areas in the validation effort, such failure modes will remain undiscovered. Additionally, attempting to apply the simulation outside the validation space requires uncertain extrapolation of trends or calculations from the nearest validated conditions, as there is no way to bound or characterize the predictive errors introduced by such extrapolation. Moreover, any validation data collected outside the intended use domain provides little value in establishing credibility.

The systems and methods as described herein represent an improvement on these existing technologies that are unable to assess product designs outside of the validation space of the corresponding simulation model. In particular, the systems and methods at least partially employ a verified and validated simulation model to assess product designs that extend beyond the validation space of the simulation model.

Current technologies require full re-verification and re-validation using physical prototypes when product designs shift outside the validation space of an existing simulation model. The systems and methods replace this lengthy process by automatically and intelligently calculating a correlation or scaling factor based on a subject product design. In particular, the systems and methods analyze specific differences between an existing product design and a subject product design to calculate the correlation or scaling factor, such as based on various factors like environmental conditions, ratings/specifications/inputs, operating conditions, etc., as discussed herein. The systems and methods employ the calculated correlation or scaling factor with the simulation model to assess compliance of the subject product design.

Accordingly, the systems and methods represent an improvement on existing simulation model technologies. In particular, by accurately simulating designs within the intended use domain (including those previously untested) but outside the validation space, the systems and methods reduce the risk of unforeseen issues. Further, as product designs evolve, the systems and methods seamlessly accommodate variations, optimizations, and innovative features. Additionally, the systems and methods identify potential compliance or safety concerns early in the design process, thereby enabling corrective actions. With reliable virtual simulations, the reliance on costly and time-consuming physical tests diminishes, and without compromising safety. Moreover, the systems and methods enable the testing and certification of unconventional and/or “future” designs.

Additionally, the systems and methods represent significantly more than a well-understood, routine, or conventional approach in the field. In particular, existing techniques require outright rejecting previously-verified models when inputs shift outside the validation space for credible certification predictions (i.e., conventional practice dictates full model replacement). In contrast, the systems and methods uniquely enable reusing existing simulation models to assess products outside the validation space, therefore enabling model validity over greater ranges. Therefore, the systems and methods enable the expanding of applications which diverges from conventional requirements that simulation models become obsolete whenever contexts shift and new data is required. As a result, while existing approaches require fully rebuilding simulations when product designs no longer match original verification parameters, the systems and methods support a flexible technique that enables ongoing re-application, which represents an unconventional solution not currently enabled in the simulation testing domain.

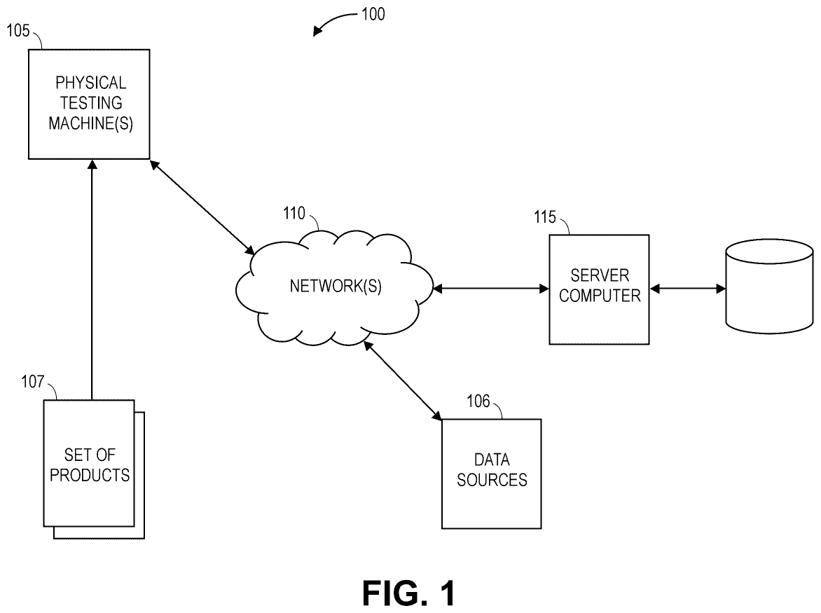

FIG. 1 illustrates an overview of a system 100 of components configured to facilitate the systems and methods. It should be appreciated that the system 100 is merely an example and that alternative or additional components are envisioned.

As illustrated in FIG. 1, the system 100 may include a set of physical testing machines 105. Generally, each physical testing machine 105 is a physical machine that may be configured to test one or more of a set of products 107, such as to assess performance of the set of products 107. In embodiments, a specific testing machine 105 may be configured to test a specific product 107 to assess compliance with a specific standard.

For example, the physical testing machine(s) 105 may be an AC dielectric test set, a tensile testing machine, a compression testing machine, a hardness testing machine, a flammability testing machine, an environmental testing chamber, a spectrophotometer, an electromagnetic compatibility (EMC) test equipment, an ingress protection (IP) testing equipment, a vibration testing machine, a salt spray chamber, a refrigerant leakage test, large scale fire tests, fire furnace tests, calorimeter tests, adiabatic explosive chambers, impact tests, sprinkler tests, fire protection tests, and/or another testing machine. Further, for example, the set of products 107 may be electronics and electrical components, aerospace and defense equipment, automotive components, pharmaceuticals and medical devices, building materials, packaging materials, solar panels and renewable energy equipment, and/or other products. Additionally, for example, the one or more standards may be set by standard-setting organizations (SSO) such as the International Organization for Standardization (ISO), National Fire Protection Association (NFPA), American National Standards Institute (ANSI), Underwriters Laboratories (UL), Institute of Electrical and Electronics Engineers (IEEE), International Electrotechnical Commission (IEC), European Committee for Standardization (CEN), and/or others.

The physical testing machine(s) 105 may be configured to communicate with a server computer 115 via one or more networks 110. According to embodiments, the physical testing machine(s) 105 may be configured to provide results of any physical tests that it conducts or facilitates to the server computer 115. The network(s) 110 may support any type of data communication via any standard or technology (e.g., GSM, CDMA, VOIP, TDMA, WCDMA, LTE, EDGE, OFDM, GPRS, EV-DO, UWB, Internet, IEEE 802 including Ethernet, WiMAX, Wi-Fi, Bluetooth, and others). The server computer 115 may be associated with an entity such as a company, business, SSO, corporation, or the like, which designs, markets, manufactures, tests, and/or sells products, or is otherwise involved in the supply chains of the products. The server computer 115 may include various components that support communication with the physical testing machine(s) 105.

The server computer 115 may communicate with one or more data sources 106 via the network(s) 110. In embodiments, the data source(s) 106 may compile, store, or otherwise access information associated with products, product tests, standards, certifications, requirements, and/or the like. In particular, the data source(s) 106 may represent SSOs, certification entities, governing bodies, and/or the like, and may provide data, to the server computer 115, indicative of or representing various product tests, standards, certifications, or the like. For example, one of the data sources 106 may represent the NFPA, and may provide, to the server computer 115, data associated with NFPA 262 or other NFPA standards.

According to embodiments, the server computer 115 may be configured to verify and validate a simulation model associated with a given standard/certification, and with a certain product, where the simulation model has an associated validation space and the certain product has an associated intended use domain. Additionally, the server computer 115 may employ various techniques to accurately use the simulation model outside of its validation space, by calculating a correlation or scaling factor between two product designs.

The server computer 115 may additionally use these techniques to determine whether a product having a design outside of the original validation space would be certified according to a standard, such as a specific standard that the server computer 115 receives or accesses from the data sources 106. In particular, the server computer 115 may assess whether a physical version of the product having this design should be certified according to the specific standard. In embodiments, the server computer 115 may facilitate certifying the physical version of the product according to the specific standard, or may interface with another entity (not shown in FIG. 1) to cause the physical version of the product to be certified according to the specific standard. Additional details regarding these functionalities are described with respect to some of the following figures.

The server computer 115 may be configured to interface with or support a memory or storage 113 capable of storing various data, such as in one or more databases or other forms of storage. According to embodiments, the storage 113 may store data or information associated with any tests that are performed or facilitated, including the results thereof, any standards for which compliance is being assessed, product designs, data associated with simulation models, and/or other data.

Although depicted as a single server computer 115 in FIG. 1, it should be appreciated that the server computer 115 may be in the form of a distributed cluster of computers, servers, machines, or the like. In this implementation, the entity may utilize the distributed server computer(s) 115 as part of an on-demand cloud computing platform. Accordingly, when the physical testing machine(s) 105 interfaces with the server computer 115, the physical testing machine(s) 105 may actually interface with one or more of a number of distributed computers, servers, machines, or the like, to facilitate the described functionalities.

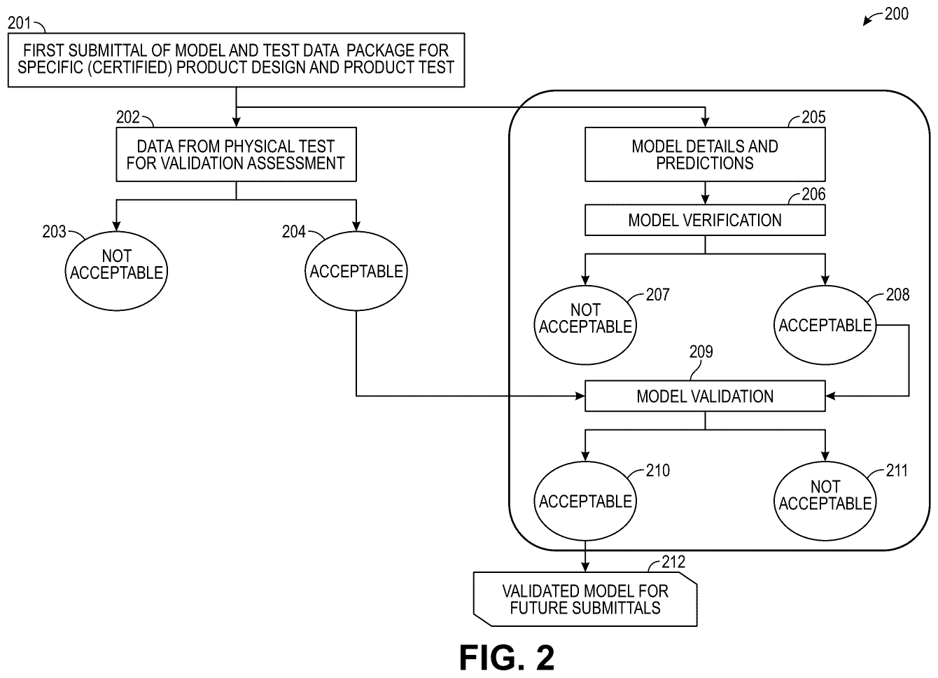

FIG. 2 illustrates a chart 200 of an existing verification and validation technique for a simulation model. In particular, the chart 200 illustrates the simulation model being validated using actual physical test results and additional requirements that extend beyond standard tests for certification, including capturing additional responses and performing different test scenarios for creating a validation space.

Block 201 represents a first submittal of a model and test data package for a specific/certified product design and product test. According to embodiments, the model may generally refer to a representation or simulation of the behavior or characteristics of the product. For example, there may be a company developing a new type of insulating material for use in home construction, and the company wants to certify an effectiveness of the insulating material in retaining heat. The company may submit its model and test data to the relevant certification authority, where the model aims to predict various thermal properties of the material, and where the test data is gathered from physical experiments. Thus, the model may be a representation of the actual product in a virtual three-dimensional, two-dimensional, or one-dimensional form (and which may be mathematical-, numerical-, computer-, or statistical-based) for determining the behavior(s) or characteristic(s) under a set of conditions or a given environment. Similarly, a simulation may be the process of solving for the results, or generally how these models behave in the set of conditions and the given environment.

Block 202 represents data from a physical test to be used for validation assessment. Continuing with the example, the certification authority may receive the test data, which for example may include measurements of the material's heat conductivity, insulation properties, and other relevant factors, and the certification authority may assess whether the data is acceptable. In particular, if the material fails to meet the required insulation standards (e.g., it conducts heat too quickly), the certification authority may reject it (block 203). If the data shows promising insulation properties (block 204), the certification authority may deem it acceptable and processing may proceed to block 209.

Generally, at block 209, the validated model may be compared against real-world observations, where the “acceptable” test data at block 204 serves as a reference or ground truth. That is, if the test data was deemed acceptable at block 204, the test data is deemed to accurately represent the material's behavior and the model's predictions should align with this data. This enables confirmation of validity: when the model consistently matches the acceptable test results, it confirms that the model is valid and reliable. Further, by using acceptable test data, the certification authority reduces the risk of approving a flawed model; if the data were not acceptable, the model might be unreliable even if it passed verification. Moreover, model validation considers both the model's theoretical predictions and its alignment with empirical data, and ensures that the model performs well across various conditions.

Block 205 represents model details and predictions. For example, the submitted model may provide details about the material's composition, thickness, and other relevant parameters, where predictions from the model may include expected heat retention, energy efficiency, and temperature stability.

Block 206 represents model verification. In particular, the certification authority may verify the model's details against the actual test data, including checking whether the model accurately predicts the material's behavior under different conditions. If discrepancies exist (e.g., the model overestimates insulation), revisions may be necessary (block 207). If the model verification is acceptable (block 208), processing may proceed to model validation (block 209).

At block 209, the validated model may undergo a set of checks. For example, the authority may compare the model's predictions with additional test results, such as those not used during model development. If the model consistently aligns with observed behavior, it may be considered valid (block 210). If not, further adjustments or recalibrations may be needed (block 211).

Block 212 represents a validated model for future submittals. Continuing with the example, once the model passes validation, it may become the certified standard, where builders, architects, and manufacturers can confidently use this material in their designs. Additionally, the validated model is now ready for future submissions, ensuring consistent performance across various applications. Generally, the simulation solutions of a validated model accurately represent the real-world physical systems and conditions of interest within the intended use domain of the validated model.

However, the existing verification and validation technique as illustrated in FIG. 2 is limited in that it cannot be used to reliably assess a product design that extends beyond the validation space of the validated model. That is, there may be a product design that is within the intended use domain of the product but outside the validation space of the validated model.

For example, there may be a simulation tool developed to predict airflow and heat transfer in laptop cooling systems to optimize thermal management. The simulation tool models fan, heat sink, and IC chip parameters to calculate temperature maps and power dissipation rates. Additionally, engineers physically tested physical laptop cooling systems using a test matrix of measurements: CPUs ranging from 2.3 to 4.2 GHz clock speeds (or other speeds), 10-60CFM mini-fan heat exhaust configs, cooling fins from 0.5 mm to 2 mm thickness, and a thermal interface material conductivity from 1-4 W/mK (or other conductivities).

The results of the simulation tool (i.e., data indicating computational fluid dynamics and heat transfer simulation) is validated using the results of the physical tests. In particular, the simulation outputs are compared to thermal imaging and sensor instrumentation at various pairings across validation points, such that the model metrics achieve tight predictive concordance within bounded operating and physical geometries.

However, due to limited physical testing data, the simulation lacks credentialing for parameters outside the validation space of the model, such as >100 W extreme gaming CPUs, exotic heat pipe structures, or liquid nitrogen subzero cooling. Therefore, these configurations reside outside the qualified validation space and are not able to be reliably tested, despite being feasible in the real product.

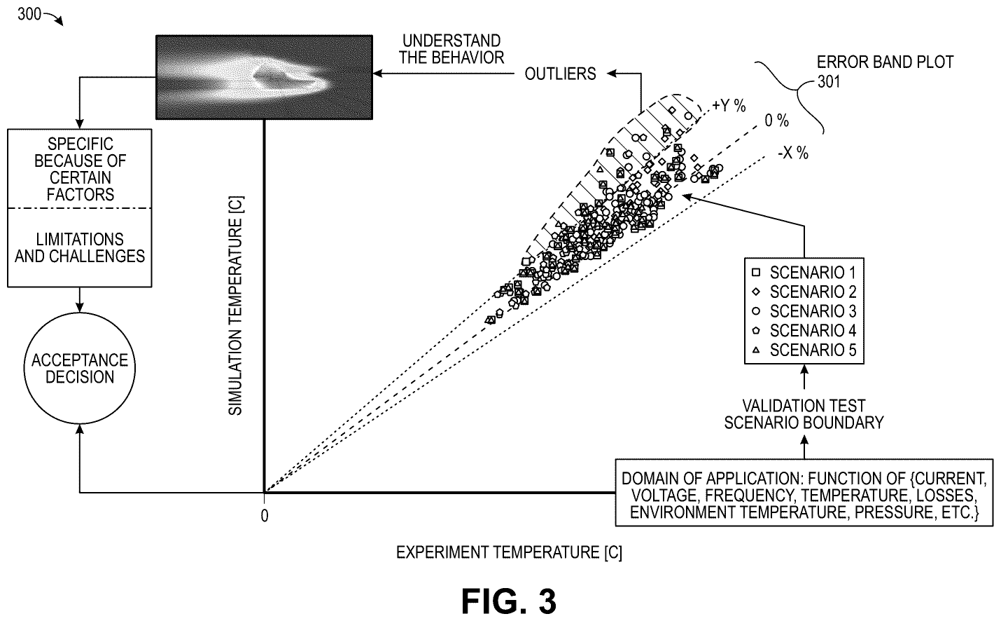

FIG. 3 illustrates a chart 300 depicting various verification and validation functionalities associated with model compliance for a temperature rise test.

The x-axis of the chart 300 is an experiment temperature and the y-axis of the chart 300 is a simulation (i.e., predicted) temperature. The predicted temperatures at various locations (e.g., more than 50 spots) resulting from the simulation are compared with the temperatures obtained for the same locations from physical tests. This comparison is repeated for a few tests at different load conditions to create the validation domain which may be used to check the robustness of the model.

An error band 301 is defined for the test as the variation of the simulation and test results from an ideal match. Any point that lies above or below the error band 301 is considered as an outlier. An investigation may be performed to understand the reason for the outliner and to categorize it. The level of detail of that investigation may depend on the deviation (i) between the physical test and the simulation, and (ii) between both results and the allowable limits in the standard. A deviation that is relatively close to the limits of a product standard may be more critical than a deviation with a significant safety margin. Depending on the error band 301, a number of outliers, and a reason(s) for such kind of specific behavior, a determination can be made as whether to consider the model to be validated and use the results for compliance.

When a subsequent submittal associated with a potential product certification is received or accessed, there may be two options for assessing the subsequent submittal. First, the existing verification and validation technique as described with respect to FIG. 2. Second, an improved verification and validation technique according to the present embodiments.

In contrast to the existing verification and validation technique as described with respect to FIG. 2, the improved verification and validation technique uses a validated model (instead of physical test results) to assess the correctness and accuracy of newly submittal models. Therefore, to assess the validity of the simulation prediction, the new model (i.e., design variance) may be benchmarked (i.e., pseudo validated) with the parent validated model.

According to embodiments, the appropriateness of the earlier validated model and a domain of applicability may be verified. Further, the systems and methods may perform a comparison of multiple models from the perspective of design, inputs, results, and outliers, which builds confidence in the ability of the model to produce reliable simulations of system performance. Hierarchy of validation assessment may be used in comparing results at different levels, which may will help avoid overlooking an error cancellation among the subsystem models.

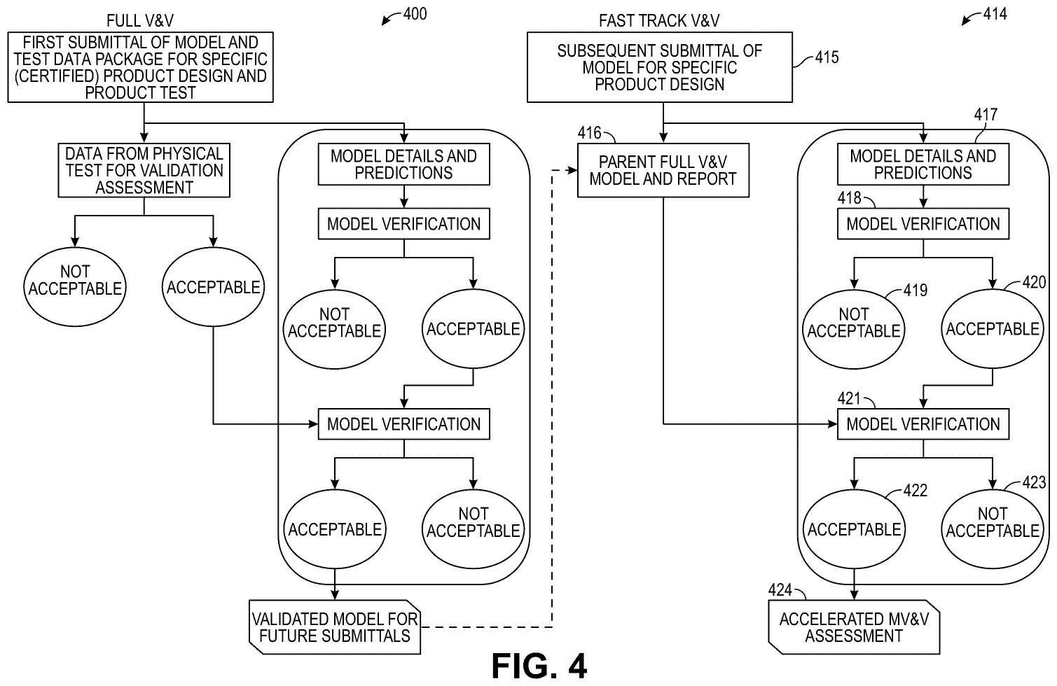

Therefore, the systems and methods as described herein enable for the use of a validated model to verify and validate a design having parameters or factors that extend beyond the validation space of the validation model, as illustrated in FIG. 4. In particular, FIG. 4 includes a chart 414 illustrating the functionalities of the systems and methods. The left side (i.e., Full V&V) of the chart 400 is the same as the chart 200 as described with respect to FIG. 2, and the right side (i.e., Fast Track V&V) of the chart 400 represents the improved technology.

Block 415 represents a subsequent submittal of a model for a specific product design. According to embodiments, the specific product design of the subsequent submittal may have a set of characteristics that fall outside the scope of the validation space of the validated model from the “Full V&V” functionality, which is represented by block 416.

Block 417 represents model details and predictions associated with the subsequent submittal of block 415. For example, the submitted model may provide details about the material's composition, thickness, and other relevant parameters, where predictions from the model may include expected heat retention, energy efficiency, and temperature stability.

Block 418 represents model verification. In particular, the certification authority may verify the model's details against the actual test data, including checking whether the model accurately predicts the material's behavior under different conditions. If discrepancies exist (e.g., the model overestimates insulation), revisions may be necessary (block 419). If the model verification is acceptable (block 420), processing may proceed to model validation (block 421).

At block 421, the validated model may undergo a set of checks. For example, the authority may compare the model's predictions with additional test results, such as those not used during model development. If the model consistently aligns with observed behavior, it may be considered valid (block 422). If not, further adjustments or recalibrations may be needed (block 423).

Block 424 may represent an assessment of the Fast Track V&V chart 414, and may represent a validated improved model for future submittals. That is, once the model passes validation, it may become an enhanced or improved standard, where builders, architects, and manufacturers can confidently use this material in their designs. Additionally, the validated improved model may now be ready for future submissions of product designs, ensuring consistent performance across various applications.

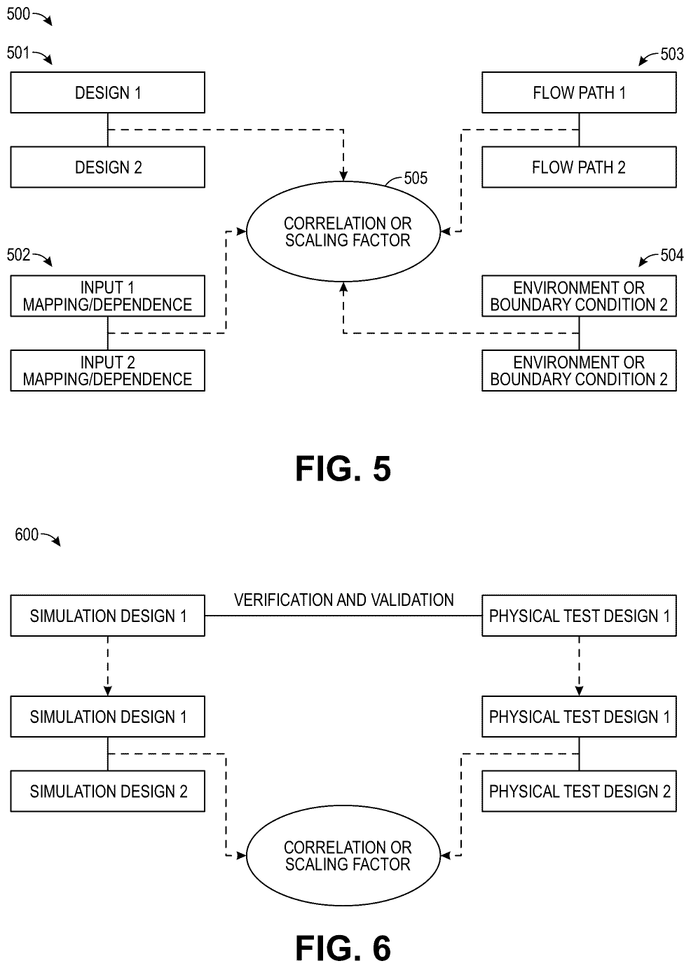

According to embodiments, a computing device may determine or compute a correlation or scaling factor between two different product designs, as illustrated by the chart 500 of FIG. 5 and as represented by reference 505. In particular, the computing device may select a set of boundaries or parameters for the improved simulation model. According to embodiments, there may be two different products from which a comparison may be performed. In particular, one of the products may be a first product having attributes or characteristics (generally, “characteristics”) that conform with the validation space of the existing model (i.e., the model resulting from the analysis as described with respect to FIG. 2), and the other of the products may be a second product having characteristics that extend beyond the validation space of the existing model.

A computing device may compare the characteristics of the first and second products. In particular, each of the first and second products may have a set of characteristics including design of components, power ratings, power loss distribution in components, testing environment, and different load conditions. It should be appreciated that additional or alternative characteristics are envisioned.

The computing device may compare a digital model (e.g., CAD model) of each design of the first and second products (501). In particular, the computing device may consider the following variables and factors associated with the digital model: size and ratings, design philosophy (i.e., overall construction and placement of components), and included sub-components, including construction details and respective size. Based on these variables and factors, the computing device may conduct quantitative and qualitative assessments.

The computing device may also determine factors associated with a mapping/dependence (502) of the first and second products. For example, the mapping/dependence factors 502 may be associated with power ratings, power loss mapping, a physical load mapping, a current mapping, an electrical/magnetic field mapping, or a fire load mapping. In the case of a power loss mapping, the power loss of a product may vary depending upon the size and components of the product. The computing device may use the normalized power loss with volume or surface area to calculate the power density for the overall product, as well as for any sub sections and/or components. The computing device may use this distribution of power loss density to understand the variation of the overall heat dissipation in the product, and that in any localized concentration, and to understand the hot spots. The computing device may use this information to quantify the power loss and heat that needs to be dissipated.

The computing device may also assess flow path factors associated therewith (503), in each of the first and second products. For example, the flow path factors 503 may be associated with a cooling path, a load path, a heat/fire path, a smoke/flow path, or a magnetic/electrical path. In the case of a cooling or heat/fire path, the heat that is generated by the various components of the product needs to be dissipated to the environment. Therefore, the computing device may determine and compare the critical heat path for the design variance. In embodiments, the critical heath path may include the orientation of components, material properties such as thermal conductivity, various interfaces and chances of air gaps, heat sink, and the flow across each component (i.e., convection) such as that driven by the fan specification and air flow path. The computing device may compare these factors to determine an appropriate increase or decrease in effectiveness.

The computing device may additionally assess any changes in the environment or surrounding boundaries (504), and in turn estimate any effect of these parameters on the simulation. For example, some of these factors include the ambient temperature, altitude, pressure, proximity to other equipment or walls, and/or others. Generally, these external factors may have a direct or indirect effect on the overall performance, thus quantification of these effects is important in the overall assessment.

The analyses of these factors enable for an in-depth qualitative and quantitative assessment of the produce design variance. In particular, the computing device may compute the correlation or scaling factor as a function of the design factor, normalized power loss density factor, normalized flow factor, and normalized temperature. This correlation or scaling factor enables the computing device to assess the critical response variation as compared to the validated model for different design variances. It should be appreciated that the computation may vary for different physics (i.e., test methods) and for different products.

The computing device may verify the correlation or scaling factor using simulation and testing results as shown in the FIG. 6. In particular, the computing device may use the validated model for determining the correlation/scaling factor for design variance. Further, the design variance(s) may be verified with the test results available for the same tests for different design variances from the physical tests.

The computing device may expand these correlation functionalities to determine the area in which the variance is non-compliant, such as in design, power loss, cooling path, environment, etc. Depending on further assessment and engineering judgment, there may be a possibility of a sub-model validation through testing of a smaller sub-section or components of the overall product, instead of testing the overall product. This can save significant effort and cost, and can provide some guidance and measure of the possible variations.

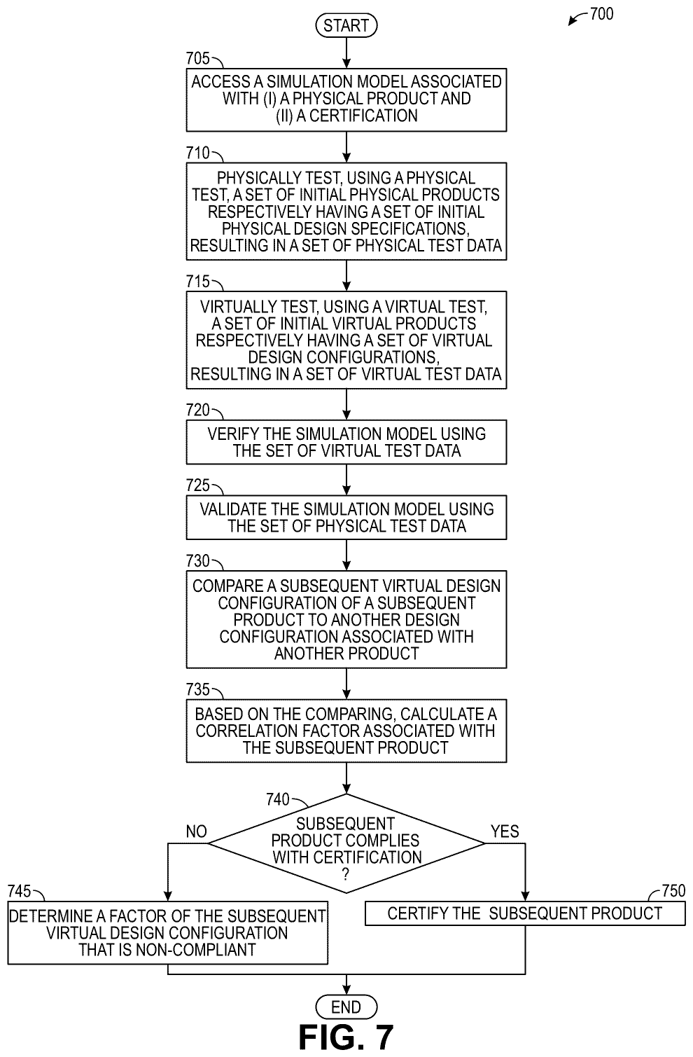

FIG. 7 depicts a block diagram of an example method 700 of assessing compliance of products defined by virtual product designs. The method 700 may be facilitated by a computing device, such as the server computer 115 as discussed with respect to FIG. 1.

The method 700 may begin at block 705 in which the computing device may access a simulation model associated with (i) a physical product and (ii) a certification. The computing device may physically test (block 710), using a physical test, a set of initial physical products respectively having a set of initial physical design configurations, the physically testing resulting in a set of physical test data.

The computing device may further virtually test (block 715), using a virtual test, a set of initial virtual products respectively having a set of initial virtual design configurations, the virtually testing resulting in a set of virtual test data. Further, the computing device may verify (block 720) the simulation model using the set of virtual test data. The computing device may also validate (block 725) the simulation model using the set of physical test data. According to embodiments, the simulation model that was verified and validated may have a validation space.

The computing device may determine whether a subsequent product having a subsequent virtual design configuration outside the validation space (but perhaps within an intended use domain of the product) complies with the certification. In particular, the computing device may compare (block 730) the subsequent virtual design configuration to another design configuration associated with another product. In a first scenario, the computing device may compare the subsequent virtual design configuration to an initial virtual design configuration of the set of initial virtual design configurations. In another scenario, the computing device may compare the subsequent virtual design configuration to an initial physical design configuration of the set of initial physical design configurations.

In embodiments, the computing device may compare a first set of factors associated with the subsequent virtual design configuration to a second set of factors associated with the another design configuration associated with the another product, wherein each of the first and second sets of factors may include at least one of: a design, a power loss mapping, a cooling path, an environment, a physical load mapping, a current mapping, an electrical/magnetic field mapping, a fire load mapping, a load path, a heat/fire path, a smoke/flow path, or a magnetic/electrical path. If the first and second sets of factors comprises the power loss mapping, the electronic device may compare a first power loss mapping associated with the subsequent virtual design configuration to a second power loss mapping associated with the another design to quantify the power loss and heat that needs to be dissipated. If the first and second sets of factors comprises the cooling path, the electronic device may compare a first critical heat path associated with the subsequent virtual design configuration to a second critical heat path associated with the another design.

At block 735, the computing device may, based on the comparing, calculate a correlation factor associated with the subsequent product. Additionally, the computing device may determine (block 740), based on the correlation factor using the simulation model that was verified and validated, whether the subsequent product would comply with the certification.

If the computing device determines that the subsequent product does not comply with the certification (“NO”), the computing device may determine (block 745) a factor of the subsequent virtual design configuration that is non-compliant. If the computing device determines that the subsequent product does comply with the certification (“YES”), the computing device may certify (block 750) the subsequent product. At this point, processing may end, repeat, or proceed to different functionality.

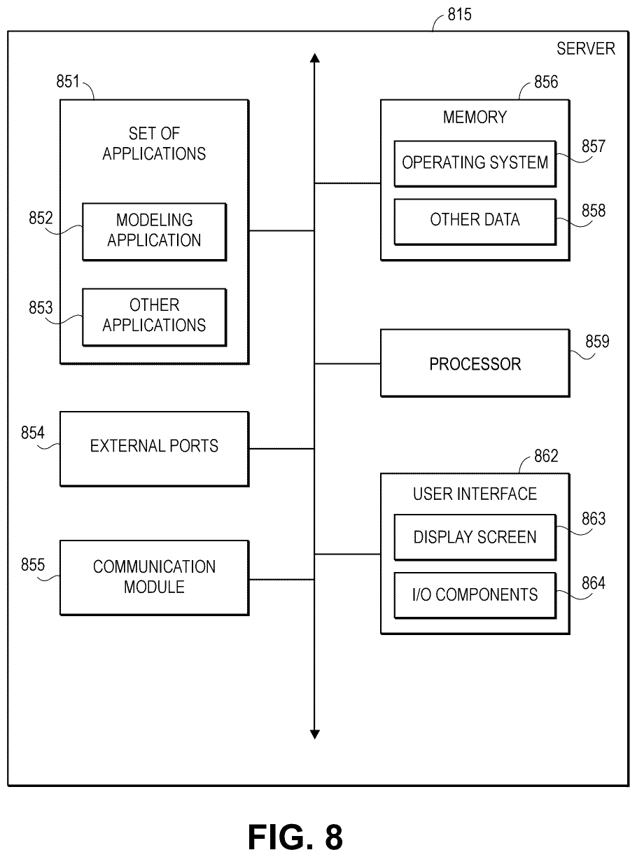

FIG. 8 illustrates a hardware diagram of an example server 815 (e.g., the server computer 115 as described with respect to FIG. 1), in which the functionalities as discussed herein may be implemented. It should be appreciated that the components of the server 815 are merely exemplary, and that additional or alternative components and arrangements thereof are envisioned. Generally, the server 815 may interface with a physical testing machine as well other components and entities via a network(s), as discussed herein.

As illustrated in FIG. 8, the server 815 may include a processor 859 as well as a memory 856. The memory 856 may store an operating system 857 capable of facilitating the functionalities as discussed herein as well as a set of applications 851 (i.e., machine readable instructions). For example, one of the set of applications 851 may be a modeling application 852 that may be configured to facilitate the improved modeling techniques as discussed herein. It should be appreciated that one or more other applications 853 are envisioned, such as an application configured to assess compliance of physical versions of virtual products with standards.

The processor 859 may interface with the memory 856 to execute the operating system 857 and the set of applications 851. According to some embodiments, the memory 856 may also store other data 858, such as product data, standards data, testing data, simulation model data, and/or other data. The memory 856 may include one or more forms of volatile and/or nonvolatile, fixed and/or removable memory, such as read-only memory (ROM), electronic programmable read-only memory (EPROM), random access memory (RAM), erasable electronic programmable read-only memory (EEPROM), and/or other hard drives, flash memory, MicroSD cards, and others.

The server 815 may further include a communication module 855 configured to communicate data via the network(s). According to some embodiments, the communication module 855 may include one or more transceivers (e.g., WAN, WWAN, WLAN, and/or WPAN transceivers) functioning in accordance with IEEE standards, 3GPP standards, or other standards, and configured to receive and transmit data via one or more external ports 854.

The server 815 may further include a user interface 862 configured to present information to a user and/or receive inputs from the user. As shown in FIG. 8, the user interface 862 may include a display screen 863 and I/O components 864 (e.g., ports, capacitive or resistive touch sensitive input panels, keys, buttons, lights, LEDs, external or built in keyboard). According to some embodiments, the user may access the server 815 via the user interface 862 to review information, make selections, and/or perform other functions.

In some embodiments, the server 815 may perform the functionalities as discussed herein as part of a “cloud” network or may otherwise communicate with other hardware or software components within the cloud to send, retrieve, or otherwise analyze data.

In general, a computer program product in accordance with an embodiment may include a computer usable storage medium (e.g., standard random access memory (RAM), an optical disc, a universal serial bus (USB) drive, or the like) having computer-readable program code embodied therein, wherein the computer-readable program code may be adapted to be executed by the processor 859 (e.g., working in connection with the operating system 857) to facilitate the functions as described herein. In this regard, the program code may be implemented in any desired language, and may be implemented as machine code, assembly code, byte code, interpretable source code or the like (e.g., via Golang, Python, Scala, C, C++, Java, Actionscript, Objective-C, Javascript, CSS, XML). In some embodiments, the computer program product may be part of a cloud network of resources.

It should be appreciated that various machine learning techniques may be used as an alternative or additional technique to the systems and methods as described herein, in particular to augment verified and validated simulation models for assessing product designs beyond a validation space. Initially, machine learning techniques may aid in feature engineering by identifying influential or relevant variables from simulation outputs to inform the behavior of the product. Additionally, these techniques may facilitate model calibration, allowing adjustments to be made based on available validation data to enhance accuracy and reliability.

Further, the machine learning techniques may train surrogate models on existing simulation data, such as to approximate the behavior of the original model across a wider range of conditions. These surrogate models may enable predictions for scenarios beyond the validation space. Additionally, data fusion techniques may integrate various data sources, such as simulation outputs, experimental results, and historical performance data, to provide more comprehensive assessments of product designs.

Furthermore, machine learning may assist in uncertainty quantification by employing probabilistic models and Bayesian approaches to estimate uncertainty associated with predictions, particularly when extrapolating beyond the validation space. The systems and methods may employ active learning strategies to guide the selection of new simulation points for validation, in particular prioritizing areas of the design space where the simulation model is least certain. Through iterative updates based on new validation data, machine learning techniques may expand the validation space and enhances the overall predictive accuracy of the simulation model. The machine learning models may be iteratively updated with new validation data to continuously improve their predictive capabilities.

Although the following text sets forth a detailed description of numerous different embodiments, it should be understood that the legal scope of the invention may be defined by the words of the claims set forth at the end of this patent. The detailed description is to be construed as exemplary only and does not describe every possible embodiment, as describing every possible embodiment would be impractical, if not impossible. One could implement numerous alternate embodiments, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Additionally, certain embodiments are described herein as including logic or a number of routines, subroutines, applications, or instructions. These may constitute either software (e.g., code embodied on a non-transitory, machine-readable medium) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that may be permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that may be temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired), or temporarily configured (e.g., programmed) to operate in a certain manner or to perform certain operations described herein. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules may provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses) that connect the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it may be communicatively coupled. A further hardware module may then, at a later time, access the memory device to retrieve and process the stored output. Hardware modules may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some example embodiments, the processor or processors may be located in a single location (e.g., within a home environment, an office environment, or as a server farm), while in other embodiments the processors may be distributed across a number of locations.

The performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “one embodiment” or “an embodiment” means that a particular element, feature, structure, or characteristic described in connection with the embodiment may be included in at least one embodiment. The appearances of the phrase “in one embodiment” in various places in the specification are not necessarily all referring to the same embodiment.

As used herein, the terms “comprises,” “comprising,” “may include,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the description. This description, and the claims that follow, should be read to include one or at least one and the singular also may include the plural unless it is obvious that it is meant otherwise.

This detailed description is to be construed as examples and does not describe every possible embodiment, as describing every possible embodiment would be impractical.

What is claimed is:

1. A computer-implemented method of assessing compliance of products defined by virtual product designs, the computer-implemented comprising:
accessing, by a computer processor, a simulation model associated with (i) a physical product and (ii) a certification;
physically testing, using a physical test, a set of initial physical products respectively having a set of initial physical design configurations, the physically testing resulting in a set of physical test data;
virtually testing, using a virtual test, a set of initial virtual products respectively having a set of initial virtual design configurations, the virtually testing resulting in a set of virtual test data;
verifying, by the computer processor, the simulation model using the set of virtual test data;
validating, by the computer processor, the simulation model using the set of physical test data, wherein the simulation model that was verified and validated has a validation space; and
determining whether a subsequent product having a subsequent virtual design configuration outside the validation space complies with the certification, including:
comparing the subsequent virtual design configuration to another design configuration associated with another product,
based on the comparing, calculating a correlation factor associated with the subsequent product, and
determining, based on the correlation factor using the simulation model that was verified and validated, whether the subsequent product would comply with the certification.

2. The computer-implemented method of claim 1, wherein comparing the subsequent virtual design configuration to the another design configuration associated with the another product comprises:
comparing the subsequent virtual design configuration to an initial virtual design configuration of the set of initial virtual design configurations.

3. The computer-implemented method of claim 1, wherein comparing the subsequent virtual design configuration to the another design configuration associated with the another product comprises:
comparing the subsequent virtual design configuration to an initial physical design configuration of the set of initial physical design configurations.

4. The computer-implemented method of claim 1, wherein comparing the subsequent virtual design configuration to the another design configuration associated with the another product comprises:
comparing a first set of factors associated with the subsequent virtual design configuration to a second set of factors associated with the another design configuration associated with the another product, wherein each of the first and second sets of factors comprises at least one of: a design, a power loss mapping, a cooling path, an environment, a physical load mapping, a current mapping, an electrical/magnetic field mapping, a fire load mapping, a load path, a heat/fire path, a smoke/flow path, or a magnetic/electrical path.

5. The computer-implemented method of claim 4, wherein each of the first and second sets of factors comprises the power loss mapping, and wherein comparing the first set of factors to the second set of factors comprises:
comparing a first power loss mapping associated with the subsequent virtual design configuration to a second power loss mapping associated with the another design to quantify the power loss and heat that needs to be dissipated.

6. The computer-implemented method of claim 4, wherein each of the first and second sets of factors comprises the cooling path, and wherein comparing the first set of factors to the second set of factors comprises:
comparing a first critical heat path associated with the subsequent virtual design configuration to a second critical heat path associated with the another design.

7. The computer-implemented method of claim 1, wherein determining, based on the correlation factor using the simulation model that was verified and validated, whether the subsequent product would comply with the certification comprises:
determining, based on the correlation factor using the simulation model that was verified and validated, that the subsequent product would not comply with the certification; and
determining, by the computer processor, a factor of the subsequent virtual design configuration that is non-compliant.

8. A system for assessing compliance of products defined by virtual product designs, comprising:
a physical testing machine configured to physically test a set of initial physical products respectively having a set of initial physical design configurations, the physical testing resulting in a set of physical test data;
a memory storing a set of computer-readable instructions; and
at least one processor interfaced with the memory, and configured to execute the set of computer-readable instructions to cause the at least one processor to:
access a simulation model associated with (i) a physical product and (ii) a certification,
virtually test, using a virtual test, a set of initial virtual products respectively having a set of initial virtual design configurations, the virtually testing resulting in a set of virtual test data,
verify the simulation model using the set of virtual test data,
validate the simulation model using the set of physical test data, wherein the simulation model that was verified and validated has a validation space, and
determine whether a subsequent product having a subsequent virtual design configuration outside the validation space complies with the certification, including:
compare the subsequent virtual design configuration to another design configuration associated with another product,
based on the comparing, calculate a correlation factor associated with the subsequent product, and
determine, based on the correlation factor using the simulation model that was verified and validated, whether the subsequent product would comply with the certification.

9. The system of claim 8, wherein to compare the subsequent virtual design configuration to the another design configuration associated with the another product, the at least one processor is configured to:
compare the subsequent virtual design configuration to an initial virtual design configuration of the set of initial virtual design configurations.

10. The system of claim 8, wherein to compare the subsequent virtual design configuration to the another design configuration associated with the another product, the at least one processor is configured to:
compare the subsequent virtual design configuration to an initial physical design configuration of the set of initial physical design configurations.

11. The system of claim 8, wherein to compare the subsequent virtual design configuration to the another design configuration associated with the another product, the at least one processor is configured to:
compare a first set of factors associated with the subsequent virtual design configuration to a second set of factors associated with the another design configuration associated with the another product, wherein each of the first and second sets of factors comprises at least one of: a design, a power loss mapping, a cooling path, an environment, a physical load mapping, a current mapping, an electrical/magnetic field mapping, a fire load mapping, a load path, a heat/fire path, a smoke/flow path, or a magnetic/electrical path.

12. The system of claim 11, wherein each of the first and second sets of factors comprises the power loss mapping, and wherein to compare the first set of factors to the second set of factors, the at least one processor is configured to:
compare a first power loss mapping associated with the subsequent virtual design configuration to a second power loss mapping associated with the another design to quantify the power loss and heat that needs to be dissipated.

13. The system of claim 11, wherein each of the first and second sets of factors comprises the cooling path, and wherein to compare the first set of factors to the second set of factors, the at least one processor is configured to:
compare a first critical heat path associated with the subsequent virtual design configuration to a second critical heat path associated with the another design.

14. The system of claim 8, wherein to determine, based on the correlation factor using the simulation model that was verified and validated, whether the subsequent product would comply with the certification, the at least one processor is configured to:
determine, based on the correlation factor using the simulation model that was verified and validated, that the subsequent product would not comply with the certification, and
determine a factor of the subsequent virtual design configuration that is non-compliant.

15. A non-transitory computer-readable storage medium configured to store instructions executable by a computer processor, the instructions comprising:
instructions for accessing a simulation model associated with (i) a physical product and (ii) a certification;
instructions for accessing a set of physical test data resulting from physically testing, using a physical test, a set of initial physical products respectively having a set of initial physical design configurations;
instructions for virtually testing, using a virtual test, a set of initial virtual products respectively having a set of initial virtual design configurations, the virtually testing resulting in a set of virtual test data;
instructions for verifying the simulation model using the set of virtual test data;
instructions for validating the simulation model using the set of physical test data, wherein the simulation model that was verified and validated has a validation space; and
instructions for determining whether a subsequent product having a subsequent virtual design configuration outside the validation space complies with the certification, including:
instructions for comparing the subsequent virtual design configuration to another design configuration associated with another product,
instructions for, based on the comparing, calculating a correlation factor associated with the subsequent product, and
instructions for determining, based on the correlation factor using the simulation model that was verified and validated, whether the subsequent product would comply with the certification.

16. The non-transitory computer-readable storage medium of claim 15, wherein the instructions for comparing the subsequent virtual design configuration to the another design configuration associated with the another product comprise:
instructions for comparing the subsequent virtual design configuration to an initial virtual design configuration of the set of initial virtual design configurations.

17. The non-transitory computer-readable storage medium of claim 15, wherein the instructions for comparing the subsequent virtual design configuration to the another design configuration associated with the another product comprise:
instructions for comparing the subsequent virtual design configuration to an initial physical design configuration of the set of initial physical design configurations.

18. The non-transitory computer-readable storage medium of claim 15, wherein the instructions for comparing the subsequent virtual design configuration to the another design configuration associated with the another product comprise:
instructions for comparing a first set of factors associated with the subsequent virtual design configuration to a second set of factors associated with the another design configuration associated with the another product, wherein each of the first and second sets of factors comprises at least one of: a design, a power loss mapping, a cooling path, an environment, a physical load mapping, a current mapping, an electrical/magnetic field mapping, a fire load mapping, a load path, a heat/fire path, a smoke/flow path, or a magnetic/electrical path.

19. The non-transitory computer-readable storage medium of claim 18, wherein each of the first and second sets of factors comprises the power loss mapping, and wherein the instructions for comparing the first set of factors to the second set of factors comprise:
instructions for comparing a first power loss mapping associated with the subsequent virtual design configuration to a second power loss mapping associated with the another design to quantify the power loss and heat that needs to be dissipated.

20. The non-transitory computer-readable storage medium of claim 18, wherein each of the first and second sets of factors comprises the cooling path, and wherein the instructions for comparing the first set of factors to the second set of factors comprise:
instructions for comparing a first critical heat path associated with the subsequent virtual design configuration to a second critical heat path associated with the another design.
